(19) United States
(12) Patent Application Publication
(10) Pub. No.: US 2020/0066943 A1
(43) Pub. Date: Feb. 27, 2020

(54) LIGHT-EMITTING APPARATUS

(71) Applicants: CITIZEN ELECTRONICS CO., LTD., Fujiyoshida-shi, Tamanashi (JP); CITIZEN WATCH CO., LTD., Nishitokyo-shi, Tokyo (JP)

(72) Inventor: Ryo TAMURA, Yamanashi (JP)

(21) Appl. No.: 16/466,495

(22) PCT Filed: Nov. 28, 2017
(86) PCT No.: PCT/JP2017/042644

§ 371 Date: Jun. 4, 2019

(30) Foreign Application Priority Data
Dec. 5, 2016 (JP) 2016-236089

(51) Int. Cl. H01L 33/48; H01L 25/075; H01L 33/50; H01L 33/56; H01L 33/62; H01L 33/64

(52) U.S. Cl. CPC H01L 33/486; H01L 25/0753; H01L 33/642; H01L 33/56; H01L 33/62; H01L 33/504

(57) ABSTRACT

Provided is a light-emitting apparatus including a mechanically strong and electrically insulated circuit board and an LED package mounted in an opening of the circuit board from the backside thereof with improved light extraction efficiency. The light-emitting apparatus includes: a circuit board having an opening; at least one LED package including a package substrate, an LED device mounted on the package substrate, and a sealing resin sealing the LED device, the LED package being inserted into the opening from the backside of the circuit board and soldered to a back surface of the circuit board at an edge of an upper surface of the package substrate; and an insulating spacer fixed on the back surface of the circuit board and enclosing sides of the package substrate. The sealing resin has an upper surface placed at the same height as or higher than an upper surface of the circuit board with respect to the back surface of the circuit board, the upper surface of the sealing resin being a light-emitting surface of the LED package.

### FIELD

The present invention relates to a light-emitting apparatus.

### BACKGROUND

Chip-On-Board (COB) LED packages are known in which LED devices are mounted on a mounting substrate, such as a ceramic or metal substrate, and sealed with a phosphor-containing resin.

Patent Literature 1 describes a light-emitting device including a planar lead frame having a first lead and a second lead, a light-emitting element mounted on the first lead, a resin frame surrounding the light-emitting element, a first sealing resin filled inside the resin frame to seal the light-emitting element, and a second sealing resin covering the resin frame and first sealing resin. In this light-emitting device, the lower end of the inner surface of the resin frame is disposed only on the first lead; the second sealing resin covers at least part of the first and second leads outside the resin frame; of the back surface of the first lead, a region immediately below the light-emitting element is exposed.

Patent Literature 2 describes a surface-mounting ceramic substrate on which a semiconductor chip (e.g., an LED chip) is mounted. This substrate is surface-mounted on a circuit board, and the body of this substrate has slits for relaxing stress on bonding parts, between portions provided with external connecting electrodes and a portion provided with a heat-sinking conductor, and has a thick part including a portion where tensile force is concentrated and being thicker than the portions provided with the electrodes.

Patent Literature 3 describes a backside-mounting LED (light-emitting diode) manufactured by mounting an LED chip on an electrode pattern formed on an insulating base substrate, sealing the LED chip with a translucent resin, and thereafter mounting the LED chip on a mounting substrate from the backside thereof so that the sealing resin is included in a through hole formed in the mounting substrate.

### CITATIONS LIST

### Patent Literature

Patent Literature 1: Japanese Unexamined Patent Publication No. 2014-209602

Patent Literature 2: Japanese Unexamined Patent Publication No. 2008-288536

Patent Literature 3: Japanese Unexamined Patent Publication No. 2008-205107

### SUMMARY

Since a COB LED package has electrodes on the upper surface of its package substrate, one possible way to manufacture a light-emitting apparatus including a COB LED package is to form an opening in a circuit board and to mount the LED package therein from the backside of the circuit board. In such a light-emitting apparatus, the circuit board needs to be thick to some extent, in order to ensure the mechanical strength of the circuit board. Since a thicker circuit board has a deeper opening, part of light emitted from the LED package is projected on the end face (inner wall) of the opening. Since the opening of a circuit board is not generally subjected to special processing for enhancing reflection, the end face has a small reflectance. Accordingly, projection of part of the emitted light on the end face results in optical loss (vignetting), which reduces efficiency of light extraction on the upper side of the circuit board.

In such a backside-mounting light-emitting apparatus, conductive patterns may also be provided on the back surface of the circuit board, and a metal heat-sinking substrate may be disposed on the backside of the circuit board as a heat sink for absorbing heat generated by the LED package. In this case, it is necessary to ensure electrical insulation between the circuit board and the heat-sinking substrate (increase the dielectric strength).

It is an object of the present invention to provide a light-emitting apparatus including a mechanically strong and electrically insulated circuit board and an LED package mounted in an opening of the circuit board from the backside thereof with improved light extraction efficiency.

Provided is a light-emitting apparatus including: a circuit board having an opening; at least one LED package including a package substrate, an LED device mounted on the package substrate, and a sealing resin sealing the LED device, the LED package being inserted into the opening from the backside of the circuit board and soldered to a back surface of the circuit board at an edge of an upper surface of the package substrate; and an insulating spacer fixed on the back surface of the circuit board and enclosing sides of the package substrate. The sealing resin has an upper surface placed at the same height as or higher than an upper surface of the circuit board with respect to the back surface of the circuit board, the upper surface of the sealing resin being a light-emitting surface of the LED package.

Preferably, in the light-emitting apparatus, the upper surface of the sealing resin is flush with the upper surface of the circuit board.

Preferably, the light-emitting apparatus further includes a heat-sinking substrate disposed on the backside of the circuit board, the heat-sinking substrate causing heat generated by the LED package to be discharged outside the apparatus, wherein the circuit board and the spacer are fixed to the heat-sinking substrate by a screw passing through both the circuit board and the spacer.

Preferably, in the light-emitting apparatus, the at least one LED package comprises a plurality of LED packages, the circuit board has openings into which the LED packages are respectively inserted, and the package substrate of each LED package is in contact with the heat-sinking substrate with an elastic heat-sinking sheet interposed therebetween.

Preferably, in the light-emitting apparatus, each LED package is separately provided with the heat-sinking sheet, and the heat-sinking sheet protrudes laterally with respect to the package substrate in each LED package.

Preferably, in the light-emitting apparatus, the circuit board has a conductive pattern on the upper surface thereof and a through hole passing through the circuit board in the thickness direction on or near an inner wall of the opening, the package substrate has a connecting electrode at an edge of the upper surface thereof, and the through hole is filled with solder to electrically connect the conductive pattern and the connecting electrode.

In the light-emitting apparatus, mechanical strength and electrical insulation of the circuit board are ensured, while efficiency of light extraction from the LED package mounted in an opening of the circuit board from the backside thereof is improved.

### BRIEF DESCRIPTION OF DRAWINGS

FIG. 1 is a top view of a light-emitting apparatus 1.

FIG. 2 is a side view of the light-emitting apparatus 1.

FIG. 3 is an exploded perspective view of the light-emitting apparatus 1.

FIG. 4 is a back view of the light-emitting apparatus 1 from which the heat-sinking substrate 3 is removed.

FIG. 5 is a partial cross-sectional view of the light-emitting apparatus 1 taken along line V-V in FIG. 1.

FIG. 6 is a top view showing conductive patterns on the circuit board 2.

FIG. 7 is a partial cross-sectional view of a light-emitting apparatus 100 of a comparative example.

FIGS. 8(A) to 8(D) are perspective views for explaining the structure and manufacturing process of the LED package 4.

FIGS. 9(A) to 9(C) are enlarged views of an opening 12 and its environs on the upper surface of the circuit board 2, and a top view of an LED package 4′.

FIG. 10 is a cross-sectional view of a light-emitting apparatus 1′ including an LED package 5.

### DESCRIPTION OF EMBODIMENTS

Hereinafter, with reference to the accompanying drawings, light-emitting apparatuses will be explained in detail. However, note that the present invention is not limited to the drawings or the embodiments described below.

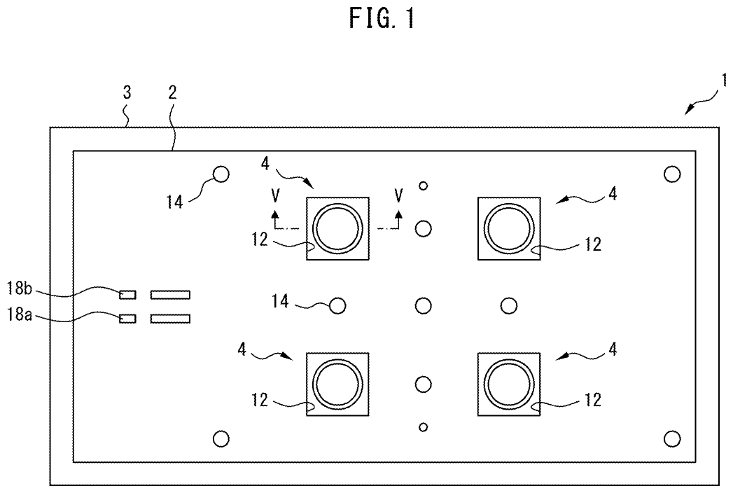

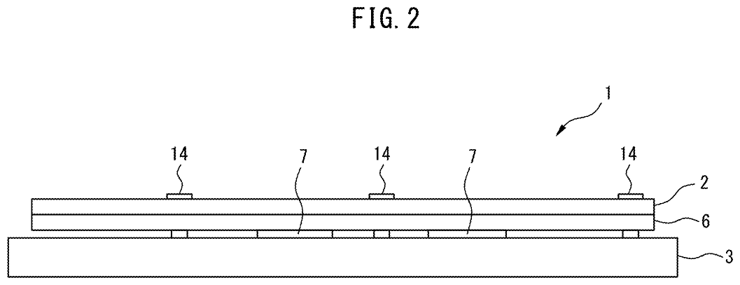

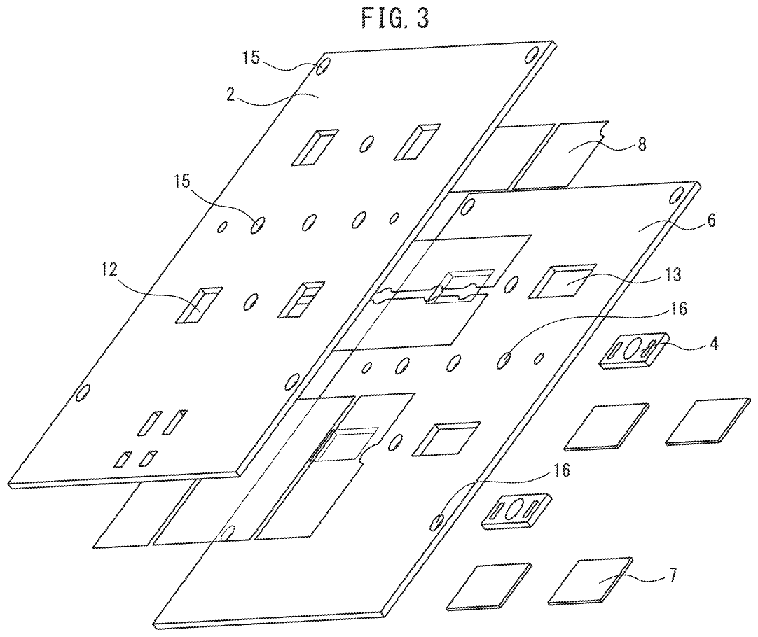

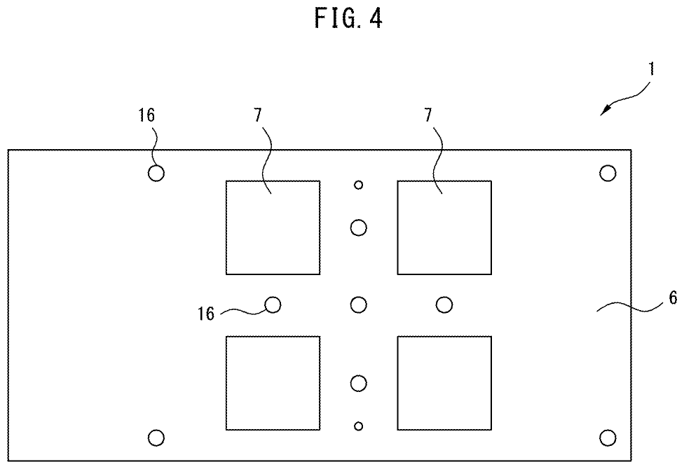

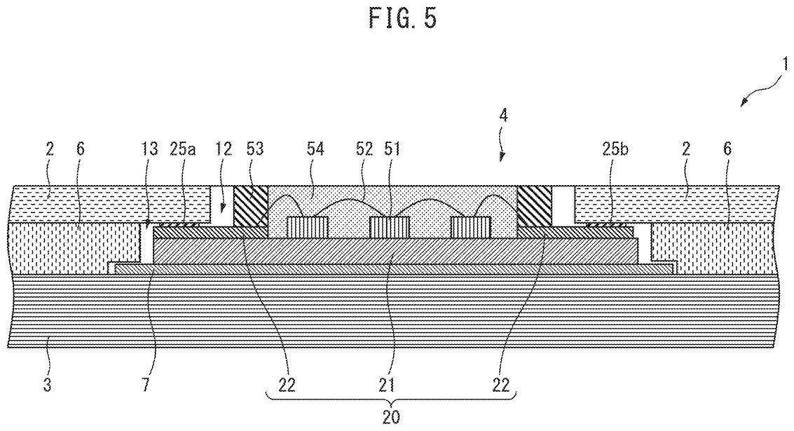

FIGS. 1 to 3 are a top view, a side view and an exploded perspective view of a light-emitting apparatus 1, respectively. The light-emitting apparatus 1 has a structure in which four LED packages 4 are mounted on a circuit board 2 from the backside thereof and a heat-sinking substrate 3 is disposed on the backside of the LED packages 4. The light-emitting apparatus 1 is used as an LED light source for various kinds of lighting equipment, for example. In FIG. 3, the heat-sinking substrate 3 is omitted from illustration. FIG. 4 is a back view of the light-emitting apparatus 1 from which the heat-sinking substrate 3 is removed. FIG. 5 is a partial cross-sectional view of the light-emitting apparatus 1 taken along line V-V in FIG. 1. Note that the number of LED packages 4 in the light-emitting apparatus is not specifically limited; it may be larger or smaller than four, or may be one.

The circuit board 2 is a rectangular insulating substrate, and is formed from a glass epoxy substrate whose base material is Flame Retardant Type 4 (FR-4), for example. In the illustrated example, the circuit board 2 has four openings 12 into which the LED packages 4 are inserted. The openings 12 each have a rectangular shape, and are arrayed in a lattice pattern having two rows and two columns. The circuit board 2 also has screw holes 15 at corners and near the center thereof. As shown in FIG. 1, screws 14 are inserted into the respective screw holes 15 to fix the circuit board 2 to the heat-sinking substrate 3.

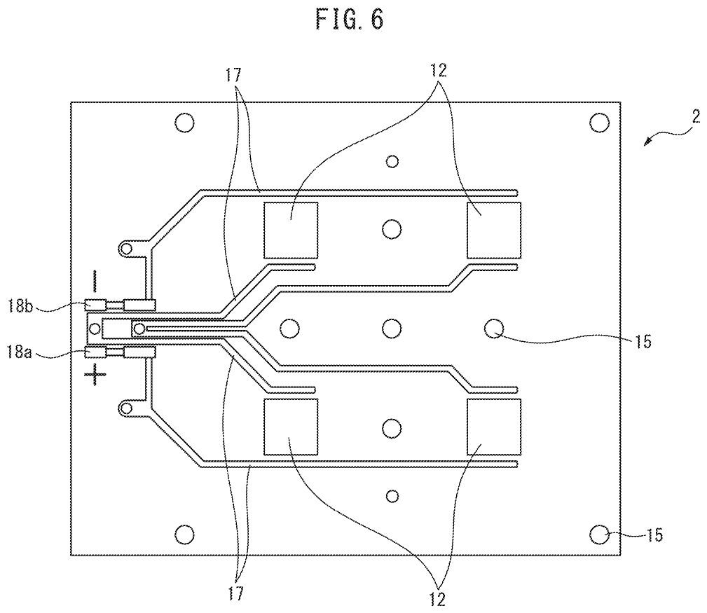

FIG. 6 is a top view showing conductive patterns on the circuit board 2. As shown in FIG. 6, the circuit board 2 includes conductive patterns 17 for electrically connecting the four LED packages 4 to each other (circuit for driving the LED packages 4), and two electrodes 18a, 18b for connecting the light-emitting apparatus 1 to an external power source. In the illustrated example, the conductive patterns 17 are formed so that the four LED packages 4 are connected in series two by two and then connected in parallel. Connecting the electrodes 18a, 18b to an external power source and applying a voltage thereacross causes the four LED packages 4 to emit light at the same time. However, the shapes and layout of the conductive patterns 17 and electrodes 18a, 18b may be different from the illustrated ones. Only some of the LED packages 4 may emit light, depending on the routing of the conductive patterns 17.

Since the upper surface of the circuit board 2 is covered with a white resist, for example, except for the portions of the openings 12, screw holes 15 and electrodes 18a, 18b, the conductive patterns 17 are not shown in FIGS. 1 and 3.

The heat sinking substrate 3 is a rectangular metal substrate disposed on the backside of the circuit board 2 and four LED packages 4. For example, the heat-sinking substrate 3 is made of aluminum or copper, which excels in heat resistance and heat dissipation, since it functions as a heat sink causing heat generated by the LED packages 4 to be discharged outside the apparatus. However, the heat-sinking substrate 3 may be made of a material other than aluminum and copper, as long as it excels in heat resistance and heat dissipation.

The spacer 6 is a rectangular board for increasing the rigidity and dielectric strength of the circuit board 2, and is approximately as thick as the circuit board 2. The spacer 6 is made of a material having heat resistance and electrical insulation, such as FR-4, similarly to the circuit board 2. The spacer 6 is layered between the circuit board 2 and the heat-sinking substrate 3, and fixed to the back surface of the circuit board 2 with a double-sided heat-resistant adhesive tape 8, for example. The spacer 6 has four rectangular openings 13 and screw holes 16 at the positions corresponding to the openings 12 and screw holes 15 of the circuit board 2, respectively, the number of screw holes 16 is the same as that of screw holes 15. As shown in FIGS. 3 and 5, the openings 13 of the spacer 6 are larger than the openings 12 of the circuit board 2, causing the back surface of the circuit board 2 to be partially exposed in the openings 13. The circuit board 2 and spacer 6 are fixed to the heat-sinking substrate 3 by the screws 14 passing through the circuit board 2 and spacer 6.

The spacer 6 may be formed as a molded plastic product, for example, and made of a material different from the circuit board 2. The circuit board 2 and spacer 6 may be bonded together with an adhesive, for example.

Each LED package 4 is a COB light-emitting unit including a package substrate 20, LED devices 51, a resin frame 53 and a sealing resin 54, as shown in FIG. 5. Each LED package 4 is inserted into the corresponding openings 12, 13 from the backside of the circuit board 2 and spacer 6, so that the package substrate 20 is in the opening 13 of the spacer 6 while the portion of the resin frame 53 and sealing resin 54 is in the opening 12 of the circuit board 2. The sides of the package substrate 20 are thus enclosed by the spacer 6. Each LED package 4 is fixed (SMT mounted) on the circuit board 2 by bonding edges of the package substrate 20 to the lower surface of the circuit board 2 exposed in the corresponding opening 13 with solder 25a, 25b.

The heat-sinking sheets 7 are thermally conductive and elastic rubber sheets made of a silicon-based material and respectively provided for the LED packages 4. Each heat-sinking sheet 7 is rectangular and larger than the package substrate 20. The package substrate 20 of each LED package 4 is in contact with the heat-sinking substrate 3 with the elastic heat-sinking sheet 7 interposed therebetween.

Mounting the LED packages 4 on the circuit board 2 may lead to variations in height of the LED packages 4, depending on their soldering. Such height variations may lead to a gap between the LED packages 4 and the heat-sinking substrate 3, resulting in insufficient heat-sinking to the heat-sinking substrate 3. However, the elastic heat-sinking sheets 7 reduce variations in height of the LED packages 4 in the light-emitting apparatus 1, which allows for stable heat conduction from the LED packages 4 to the heat-sinking substrate 3.

In each LED package 4, the heat-sinking sheet 7 protrudes laterally with respect to the package substrate 20, as shown in FIG. 5. Since the heat-sinking sheet 7 ensures electrical insulation between the LED package 4 and the heat-sinking substrate 3, in terms of electrical insulation, the heat-sinking sheet 7 preferably protrudes in the horizontal direction with respect to the package substrate 20 as in the illustrated example, so that the width (creepage distance) of the protruded portion may be as long as possible. As shown in FIG. 5, each opening 13 of the spacer 6 has a step midway in the thickness direction so as to match the sizes of the package substrate 20 and heat-sinking sheet 7, which makes the diameter of each opening 13 be larger on the backside than on the upper side. However, the openings 13 of the spacer 6 may not have such steps; a gap may be exist between the circuit board 2 and the heat-sinking sheet 7 around the package substrate 20.

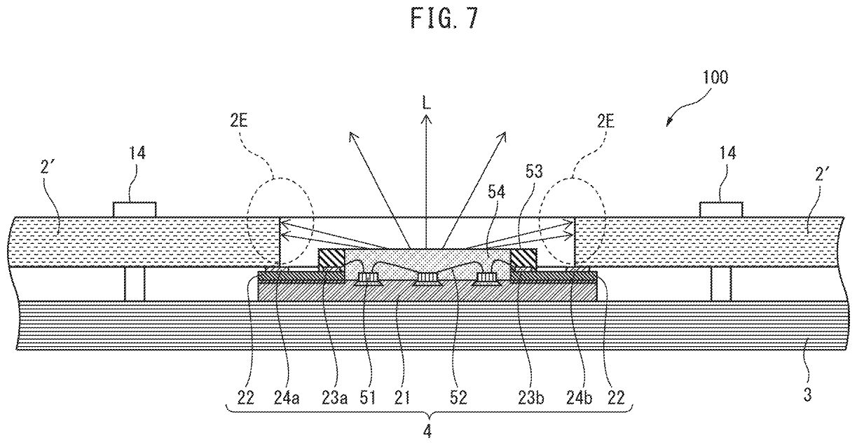

FIG. 7 is a partial cross-sectional view of a light-emitting apparatus 100 of a comparative example. The light-emitting apparatus 100 includes a circuit board 2′, a heat-sinking substrate 3 and LED packages 4. Each LED package 4 includes a metal substrate 21, an insulating substrate 22, LED devices 51, a resin frame 53 and a sealing resin 54. The LED devices 51 are mounted at the center of the upper surface of the metal substrate 21, electrically connected through wires 52 to conductive patterns 23a. 23b on the insulating substrate 22 fixed on the rim of the upper surface of the metal substrate 21, and sealed with the sealing resin 54 filled inside the resin frame 53 on the insulating substrate 22. Each LED package 4 is inserted into the corresponding opening of the circuit board 2′ from the backside thereof, and soldered to the circuit board 2′ at connecting electrodes 24a. 24b formed on edges of the upper surface of the insulating substrate 22. The heat-sinking substrate 3 is disposed on the backside of the circuit board 2′ and LED packages 4, and fixed to the circuit board 2′ by screws 14.

For example, the thickness of the circuit board 2′ of the light-emitting apparatus 100 is 1 mm, while that of the circuit board 2 of the light-emitting apparatus 1 is 0.5 mm, which is half the thickness of the circuit board 2′. Although the circuit board 2 of the light-emitting apparatus 1 is thinner than that of the light-emitting apparatus 100, the thickness of the circuit board 2 and spacer 6 in total is substantially the same as that of the circuit board 2′. In the light-emitting apparatus 1, the spacer 6 enables the circuit board to be thinner than that of the light-emitting apparatus 100, while ensuring the rigidity (mechanical strength) of the circuit board.

In the light-emitting apparatus 100, the upper surface of each sealing resin 54, which is the light-emitting surface of the LED package 4, is lower than the upper surface of the circuit board 2′, as shown in FIG. 7, resulting in the light-emitting surfaces lowered in the openings of the circuit board 2′. However, in the light-emitting apparatus 1, the upper surface of each sealing resin 54 (light-emitting surface) is (substantially) flush with the upper surface of the circuit board 2, as shown in FIG. 5. Since the circuit board 2 of the light-emitting apparatus 1 is thinner than that of the light-emitting apparatus 100, it is easy to avoid the light-emitting surfaces from being lowered in the openings 12 of the circuit board 2, without thickening the resin frame 53 and sealing resin 54 of each LED package 4. Unlike the illustrated example, the upper surface of each sealing resin 54 may be higher than that of the circuit board 2. In other words, it is only necessary that the upper surface of the sealing resin 54, which is the light-emitting surface of the LED package 4, is placed at the same height as or higher than the upper surface of the circuit board 2 with respect to the back surface of the circuit board 2.

In the light-emitting apparatus 100, part of light L emitted from each LED package 4 is projected on the end face 2E (inner wall) of the corresponding opening of the circuit board 2′, resulting in optical loss (vignetting). The light flux generated by the light-emitting apparatus 100 decreases by about 2% as compared to when the LED packages 4 emit light alone. In the light-emitting apparatus 100, even if the resin frame 53 and sealing resin 54 are thickened to raise the light-emitting surface above the opening of the circuit board 2′, the distance from the LED devices 51 to the upper surface of the sealing resin 54 becomes longer correspondingly; accordingly, decrease in light extraction efficiency need not be necessarily reduced.

In contrast, the light flux generated by the light-emitting apparatus 1 decreases only by about 0.4% as compared to when the LED packages 4 emit light alone, and is substantially the same as when the packages emit light alone. In other words, decrease in light flux of the light-emitting apparatus 1 due to back-surface mounting of the LED packages 4 is reduced by 1.6% as compared to the case of the light-emitting apparatus 100. The spacer 6 of the light-emitting apparatus 1 allows for reducing the thickness of the circuit board 2 (depth of the openings 12) without changing the thickness of the LED packages 4, which prevents the light flux from decreasing.

Further, in the light-emitting apparatus 1, the spacer 6 ensures electrical insulation between the circuit board 2 and the heat-sinking substrate 3 even when the circuit board 2 is fixed to the heat-sinking substrate 3, which increases the dielectric strength.

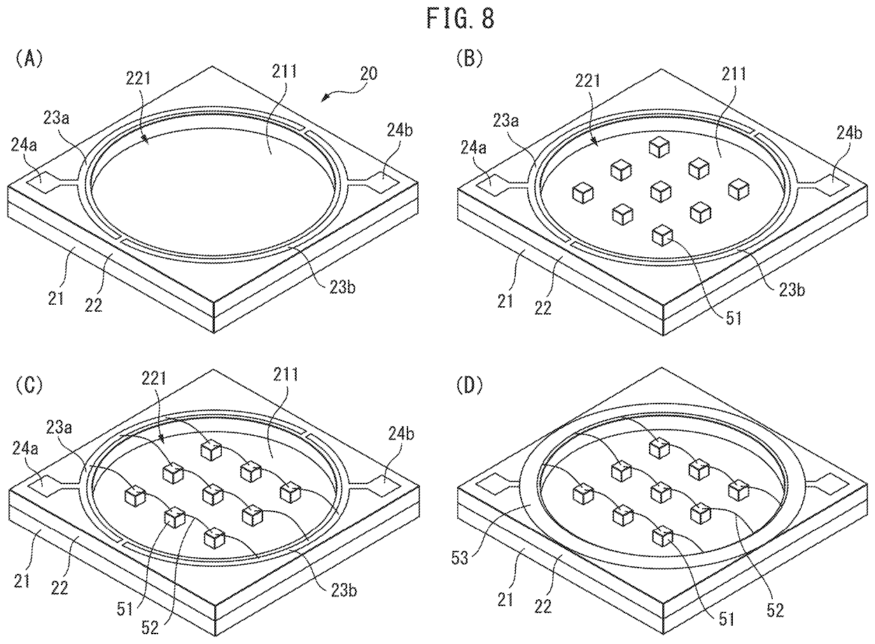

FIGS. 8(A) to 8(D) are perspective views for explaining the structure and manufacturing process of the LED package 4. Hereinafter, the structure of the LED package 4 will be described in detail.

As shown in FIG. 8(A), the package substrate 20 is constructed by bonding an insulating substrate 22 having an opening 221 at the center thereof onto the upper surface of a metal substrate 21, and has a rectangular shape as a whole. The upper surface of the metal substrate 21 includes a mounting region 211 on which the LED devices 51 are mounted at the center thereof, while the back surface of the metal substrate 21 is in contact with the heat-sinking substrate 3 with the heat-sinking sheet 7 interposed therebetween. Since the metal substrate 21 has the function of dissipating heat generated by the LED devices 51 and phosphor particles described later toward the heat-sinking substrate 3, it is made of aluminum or copper, for example, similarly to the heat-sinking substrate 3.

The upper surface of the insulating substrate 22 has arc-shaped conductive patterns 23a. 23b respectively disposed on one and the other sides of a center line halving the opening 221 so as to enclose the opening 221. The upper surface of the insulating substrate 22 also has connecting electrodes 24a, 24b respectively connected to the conductive patterns 23a, 23b at one and the other corners located diagonally. Connecting the connecting electrodes 24a. 24b to the circuit board 2 and applying a voltage thereacross causes the LED devices 51 of the LED package 4 to emit light.

The LED devices 51 are blue LEDs made of a gallium nitride compound semiconductor, for example, and emit blue light at a wavelength in the range of about 450 to 460 nm. However, the emission wavelength of the LED devices 51 is not specifically limited. The LED devices 51 may be green LEDs emitting green light or red LEDs emitting red light, for example. Further, the emission wavelength of the LED devices 51 may be different between the LED packages 4. For example, the LED devices 51 in some of the LED packages 4 may be blue LEDs, while those of the other LED packages 4 may be green LEDs.

As shown in FIG. 8(B), in each LED package 4, the LED devices 51 are mounted in a rectangular lattice pattern on the circular mounting region 211. For simplicity, FIG. 8(B) shows an example where nine LED devices 51 are mounted. However, the number of LED devices 51 included in each LED package 4 is not specifically limited; it may be larger or smaller than nine, or may be one.

The lower surfaces of the LED devices 51 are fixed on the upper surface of the metal substrate 21 with an electrically insulating transparent adhesive, for example. Each LED device 51 includes a pair of device electrodes on the upper surface thereof. As shown in FIG. 8(C), the device electrodes of adjacent LED devices 51 are electrically connected to each other by wires (bonding wires) 52. The wires 52 extending from the LED devices 51 located at edges of the mounting region 211 are connected to the conductive pattern 23a or 23b of the insulating substrate 22. Accordingly, the LED devices 51 are supplied with a current through the wires 52.

The resin frame 53 is a circular white resin frame, for example, which matches the size of the mounting region 211, and is fixed on the upper surface of the insulating substrate 22 so as to overlap the conductive patterns 23a, 23b fringing the mounting region 211. The resin frame 53 is a dam member preventing the sealing resin 54 from flowing out, and causes light emitted laterally from the LED devices 51 to reflect toward the upper side of the LED package 4 (circuit board 2).

The sealing resin 54 is a colorless and transparent thermosetting resin, such as an epoxy or silicone resin, and filled into a space on the mounting region 211 enclosed by the resin frame 53 to integrally cover and protect (seal) the LED devices 51 and wires 52. The sealing resin 54 may contain a phosphor excited by the LED devices 51. For example, if the LED devices 51 are blue LEDs, the sealing resin 54 may contain a yellow phosphor, such as yttrium aluminum garnet (YAG). In this case, the LED package 4 mixes blue light emitted from the LED devices 51 and yellow light generated by exciting the yellow phosphor with the blue light, thereby emitting white light. Alternatively, the sealing resin 54 may contain two or more phosphors, such as yellow and red phosphors, or contain a different phosphor for each LED package 4.

In manufacturing the LED package 4, as shown in FIG. 8(B), the LED devices 51 are mounted on the mounting region 211 of the package substrate 20 shown in FIG. 8(A). As shown in FIG. 8(C), the LED devices 51 are electrically connected through wires 52 to each other and to the conductive patterns 23a, 23b. Next, as shown in FIG. 8(D), the resin frame 53 is formed around the opening 221 on the upper surface of the insulating substrate 22. Thereafter, the sealing resin 54 is filled into a region enclosed by the resin frame 53. In this way, the LED package 4 is completed.

The mounting region 211 of the metal substrate 21, the opening 221 of the insulating substrate 22, and the resin frame 53 are circular in the example shown in FIGS. 8(A) to 8(D), but may by rectangular. In particular, if a large number of LED devices 51 are mounted at high density, the LED devices 51 are preferably arranged in a rectangular lattice pattern on a rectangular mounting region 211. The connecting electrodes 24a. 24b need not be necessarily disposed at corners located diagonally on the insulating substrate 22.

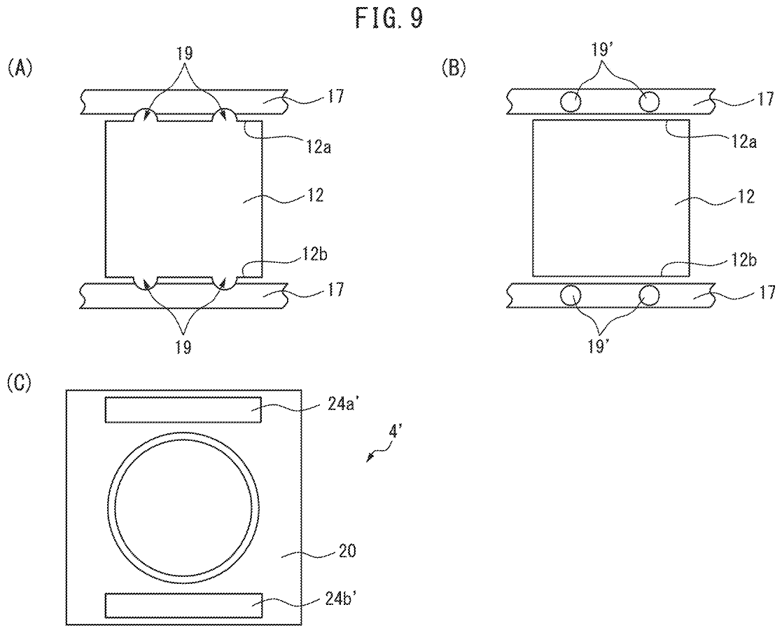

FIGS. 9(A) and 9(B) are enlarged views of an opening 12 and its environs on the upper surface of the circuit board 2. For example, the circuit board 2 may have semicircular through holes 19 passing therethrough in the thickness direction on two opposite inner walls 12a, 12b of each opening 12, as shown in FIG. 9(A). Alternatively, instead of the through holes 19, for example, the circuit board 2 may have circular through holes 19′ passing therethrough in the thickness direction near the inner walls 12a, 12b of each opening 12, as shown in FIG. 9(B). The through holes 19, 19′ are filled with solder (solder 25a, 25b in FIG. 5) to electrically connect the conductive patterns 17 on the upper surface of the circuit board 2 and the connecting electrodes of the LED packages, and are formed on the conductive patterns 17. The through holes 19, 19′ filled with solder also mechanically strengthen the connection between the circuit board 2 and the LED packages.

FIG. 9(C) is a top view of an LED package 4′. The LED package 4′ differs from the LED package 4 in that the former has connecting electrodes 24a′, 24b′ disposed along two opposite sides of the package substrate 20. Since the through holes 19, 19′ are formed so as to be aligned with the connecting electrodes of the LED packages mounted on the circuit board 2, such an LED package 4′ as shown in FIG. 9(C) is used for the circuit boards shown in FIGS. 9(A) and 9(B). Although both sides of the opening 12 have two through holes 19, 19′ in the illustrated examples, the number thereof is not specifically limited; each side may have one or more than two through holes 19, 19′. Such through holes need not be semicircular or circular, and may have rectangular or other shapes.

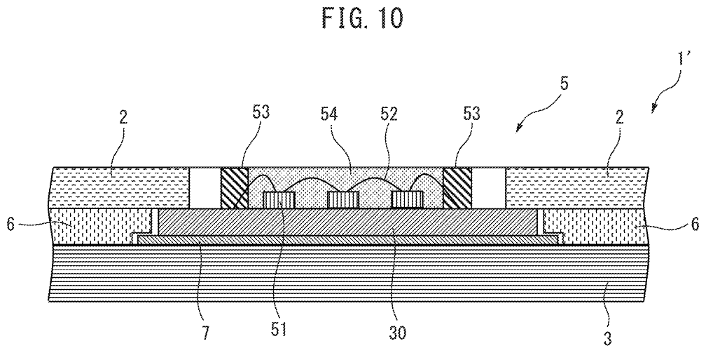

FIG. 10 is a cross-sectional view of a light-emitting apparatus 1′ including an LED package 5. The LED package 5 is identical in structure to the LED package 4, except that the former includes a ceramic substrate 30 instead of the package substrate 20 constructed by bonding the metal substrate 21 and insulating substrate 22 together. The ceramic substrate 30 is also an example of the package substrate. The light-emitting apparatus 1 may include the LED package 5 shown in FIG. 10 instead of the LED package 4. The ceramic substrate 30 is a flat substrate having an upper surface on which conductive patterns and connecting electrodes are formed and the LED devices 51 are mounted, and has the functions of the metal substrate 21 and insulating substrate 22 of the LED package 4. Since ceramics has relatively large thermal conductivity, use of a ceramic substrate enables the package substrate to be flat without any opening.

1. A light-emitting apparatus comprising:
a circuit board having an opening;
at least one LED package including a package substrate, an LED device mounted on the package substrate, and a sealing resin sealing the LED device, the LED package being inserted into the opening from the backside of the circuit board and soldered to a back surface of the circuit board at an edge of an upper surface of the package substrate; and
an insulating spacer fixed on the back surface of the circuit board and enclosing sides of the package substrate, wherein
the sealing resin has an upper surface placed at the same height as or higher than an upper surface of the circuit board with respect to the back surface of the circuit board, the upper surface of the sealing resin being a light-emitting surface of the LED package.

2. The light-emitting apparatus according to claim 1, wherein the upper surface of the sealing resin is flush with the upper surface of the circuit board.

3. The light-emitting apparatus according to claim 1, further comprising a heat-sinking substrate disposed on the backside of the circuit board, the heat-sinking substrate causing heat generated by the LED package to be discharged outside the apparatus, wherein
the circuit board and the spacer are fixed to the heat-sinking substrate by a screw passing through both the circuit board and the spacer.

4. The light-emitting apparatus according to claim 3, wherein
the at least one LED package comprises a plurality of LED packages,
the circuit board has openings into which the LED packages are respectively inserted, and
the package substrate of each LED package is in contact with the heat-sinking substrate with an elastic heat-sinking sheet interposed therebetween.

5. The light-emitting apparatus according to claim 4, wherein
each LED package is separately provided with the heat-sinking sheet, and
the heat-sinking sheet protrudes laterally with respect to the package substrate in each LED package.

6. The light-emitting apparatus according to claim 1, wherein
the circuit board has a conductive pattern on the upper surface thereof and a through hole passing through the circuit board in the thickness direction on or near an inner wall of the opening,
the package substrate has a connecting electrode at an edge of the upper surface thereof, and
the through hole is filled with solder to electrically connect the conductive pattern and the connecting electrode.
